(19) United States
(12) Patent Application Publication
(10) Pub. No.: US 2025/0202479 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventors: Natsumi IKEDA, Tokyo (JP); Yasushi NAKAHARA, Tokyo (JP); Hideki SUGIYAMA, Tokyo (JP)

(21) Appl. No.: 18/950,425

(22) Filed: Nov. 18, 2024

(30) Foreign Application Priority Data
Dec. 15, 2023 (JP) 2023-212398

(51) Int. Cl. H03K 17/687; H01L 21/8238; H01L 27/092; H03K 3/037; H03K 19/20

(52) U.S. Cl. CPC H03K 17/6871; H03K 3/037; H03K 19/20; H10D 84/0167; H10D 84/038; H10D 84/856

(57) ABSTRACT

A semiconductor device includes three types of cells as a plurality of logic gates. A first cell includes a p-type MOSFET having a first threshold voltage and an n-type MOSFET having a second threshold voltage. A second cell includes a p-type MOSFET having a third threshold voltage and an n-type MOSFET having a fourth threshold voltage. A third cell includes a p-type MOSFET having the third threshold voltage and an n-type MOSFET having the second threshold voltage. An absolute value of the first threshold voltage is higher than an absolute value of the third threshold voltage, and an absolute value of the second threshold voltage is higher than an absolute value of the fourth threshold voltage.

### CROSS-REFERENCE TO RELATED APPLICATIONS

The disclosure of Japanese Patent Application No. 2023-212398 filed on Dec. 15, 2023 including the specification, drawings and abstract is incorporated herein by reference in its entirety.

### BACKGROUND

The present invention relates to a semiconductor device and a method of manufacturing the same.

There are disclosed techniques listed below.
[Patent Document 1] Japanese Unexamined Patent Application Publication No. 2008-305950

A semiconductor device having a logic gate including a p-channel MOSFET and an n-channel MOSFET is known. Patent Document 1 discloses a semiconductor device having a logic gate including a p-channel MOSFET and an n-channel MOSFET.

### SUMMARY

There has been a demand for a semiconductor device having a logic gate to further increase an operation speed of the logic gate and further reduce power consumption.

Generally, in a semiconductor device having a logic gate including a p-channel MOSFET and an n-channel MOSFET, to increase an operation speed, that is, a switching operation, it is necessary to lower a gate threshold voltage of a FET. On the other hand, in a FET having a low gate threshold voltage, a leakage current is relatively large when the FET is turned OFF, thereby increasing power consumption.

As described above, there is usually a trade-off relationship between the operation speed and the power consumption in the logic gate including the p-channel MOSFET and the n-channel MOSFET. To further improve the operation speed and the power consumption, for example, developing a new device increases financial and time costs.

It is necessary for the semiconductor device including the logic gate to improve the balance between the operation speed and the power consumption while suppressing costs.

In a representative embodiment, a semiconductor device includes three types of cells as a plurality of logic gates. A first cell includes a p-channel MOSFET having a first threshold voltage and an n-channel MOSFET having a second threshold voltage. MOSFET having a third A second cell includes a p-channel threshold voltage and an n-channel MOSFET having a fourth threshold voltage. A third cell includes a p-channel MOSFET having the third threshold voltage and an n-channel MOSFET having the second threshold voltage. An absolute value of the first threshold voltage is higher than an absolute value of the third threshold voltage, and an absolute value of the second threshold voltage is higher than an absolute value of the fourth threshold voltage.

According to the embodiment, in the semiconductor device including the logic gate, it is possible to improve the balance between the operation speed and the power consumption while suppressing costs.

### BRIEF DESCRIPTION OF THE DRAWINGS

FIG. 1 is a diagram illustrating a configuration example of a representative logic gate as a cell.

FIG. 2 is a diagram illustrating a state where a leakage current flows in the cell.

FIG. 3 is a diagram illustrating an example of a rise time and a fall time of an output in the cell.

FIG. 4 is a graph illustrating an example of relationships between driving power ratios and cell leakages of cells regarding an LVT cell and an HVT cell.

FIG. 5 is a graph illustrating an example of relationships between driving power ratios and cell leakages of cells regarding an MVT cell.

FIG. 6 is a diagram illustrating a configuration example of a semiconductor device according to a first embodiment.

FIG. 7 is a diagram illustrating a configuration example of a third cell according to the first embodiment.

FIG. 8 is a graph illustrating relationships between driving powers and cell leakages for three types of cells according to the first embodiment.

FIG. 9 is a diagram illustrating estimation of an effect of reducing cell leakage by cell replacement according to the first embodiment.

FIG. 10 is a graph illustrating an example of relationships between the driving powers and the cell leakages of the cells according to the first embodiment.

FIG. 11 is a graph illustrating an example of relationships between operation speeds and the cell leakages of the cells according to the first embodiment.

FIG. 12 is a flowchart illustrating an example of a method of manufacturing the cells according to the first embodiment.

FIG. 13 is a flowchart illustrating an example of a well formation process according to the first embodiment.

FIG. 14 is a flowchart illustrating an example of a gate formation process according to the first embodiment.

FIG. 15 is a diagram illustrating an example of the three types of cells laid out on a semiconductor substrate according to the first embodiment.

FIG. 16 is a diagram illustrating an example of four types of masks according to the first embodiment.

FIG. 17 is a flowchart illustrating an example of an impurity implantation process for adjusting a threshold voltage according to the first embodiment.

FIG. 18 is a diagram illustrating configuration examples of NOT (INV) type cells according to a second embodiment.

FIG. 19 is a graph illustrating an example of relationships between operation speeds and cell leakages of the cells according to the second embodiment.

FIG. 20 is a diagram illustrating a configuration example of a combination circuit according to the related art.

FIG. 21 is a diagram illustrating a configuration example of a combination circuit according to a third embodiment.

FIG. 22 is a diagram illustrating a configuration example of a NAND circuit type cell according to a fourth embodiment.

FIG. 23 is a graph illustrating an example of a relationship between the number of stages of vertically stacked n-type MOSFETs and an ON current in the NAND circuit type cell according to the fourth embodiment.

FIG. 24 is a diagram illustrating an example of applying an HVT(p) cell and an LVT(n) cell to the NAND circuit type cell according to the fourth embodiment.

### DETAILED DESCRIPTION

### Background of Examination by Inventors

A semiconductor device including a digital logic circuit is known. The digital logic circuit includes a plurality of logic gates. Each logic gate includes a p-channel MOSFET connected to a line on a high potential side of a power supply and an n-channel MOSFET connected to a line on a low potential side of the same power supply. Such a semiconductor device is, for example, an integrated circuit, and as a specific example, there is a semiconductor chip obtained by dicing a semiconductor wafer.

Generally, mask and layout design of a digital logic circuit, for example, a CMOS digital logic circuit, is performed by combining basic circuits standardized and provided in advance. The basic circuit is usually referred to as a cell. The cell is a logic gate or a circuit in which logic gates are combined. Examples of the cell include logic gates such as NOT (INV), NAND, NOR, AND-OR-INV (AOI), and OR-AND-INV (OAI). Further, examples of the cell also include basic logic circuits such as flip-flops and multiplexers and auxiliary circuits such as gated clocks, buffers, and delay circuits.

A set of cells provided in advance as described above is referred to as a “cell library”. In the design of the digital logic circuit, a desired digital logic circuit is designed by laying out cells selected from the cell library on semiconductor substrate and connecting the cells by wiring.

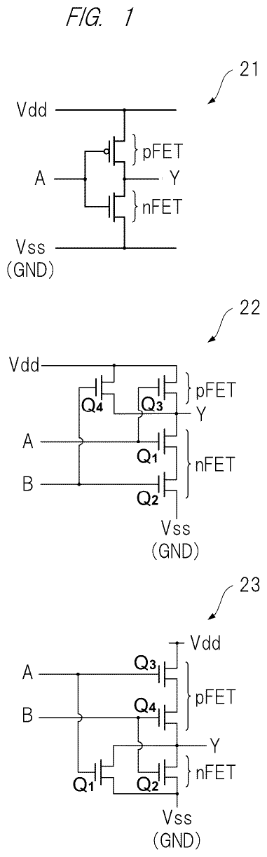

FIG. 1 illustrates configuration examples of a NOT (INV) type cell 21, a NAND type cell 22, and a NOR type cell 23. In FIG. 1, Vdd indicates the line on the high potential side of the power supply. Vss or GND indicates the line on the low potential side of the same power supply. Further, A and B indicate input terminals, and Y indicates an output terminal. As illustrated in FIG. 1, each logic gate includes a p-channel MOSFET connected to the line Vdd on the high potential side of the power supply and an n-channel MOSFET connected to the line Vss or GND on the low potential side of the same power supply.

Note that in the present specification and drawings, the p-channel MOSFET may be referred to as a p-type MOSFET or a pFET. Further, the n-channel MOSFET may be referred to as an n-type MOSFET or an nFET.

The logic gates are basic constituent parts of the cells. Multiple types of the cells, for example, 1000 patterns or more of cells are provided as logic gates according to differences in purpose (function), size, operation speed, driving power, and the like.

In recent years, a semiconductor device including digital logic circuits including such logic gates is required to achieve both an increase in operation speed and a reduction in power consumption.

In general, to increase the operation speed of the semiconductor device including cells, it is necessary to configure a logic gate by combining a p-type MOSFET having a low absolute value of a gate threshold voltage Vt with an n-type MOSFET having a low absolute value of the gate threshold voltage Vt. However, when the absolute value of the gate threshold voltage Vt decreases, the leakage current when the MOSFET is turned OFF increases, and the power consumption increases. In other words, in the semiconductor device including the MOSFET, there is a trade-off relationship between the operation speed and the power consumption. Hereinafter, a relationship between the leakage current and the operation speed in the MOSFET will be described.

Here, the leakage current flowing through the cell is also referred to as cell leakage. Further, a current flowing through the MOSFET when the MOSFET is turned ON is also referred to as an ON current, and a leakage current flowing through the MOSFET when the MOSFET is turned OFF is also referred to as an OFF leakage.

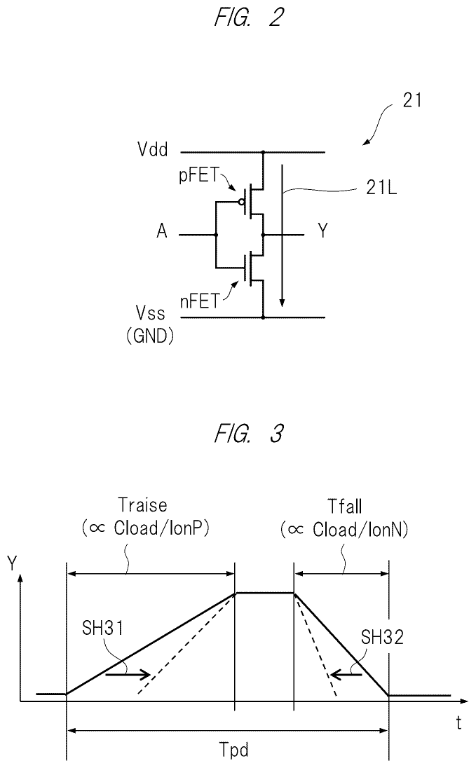

FIG. 2 illustrates an example of the NOT (INV) type cell 21 which is a representative cell in a CMOS circuit. As illustrated in FIG. 2, when an ON signal is input to the input terminal A of the NOT type cell 21, an OFF leakage 21L of the NOT type cell 21 is determined by an OFF leakage value IoffP of the p-type MOSFET. In contrast, when an OFF signal is input to the input terminal A, the OFF leakage 21L of the NOT type cell 21 is determined by an OFF leakage value IoffN of the n-type MOSFET. In an operation of the NOT type cell 21, when assuming that a time during which the ON signal is input to the input terminal A and a time during which the OFF signal is input to the input terminal A are approximately the same, an average leakage current per unit time Ileak_ave can be represented by Expression (1) described below.

$$\begin{matrix}[ Expression 1 ] & \\ Ileak\_ave = ( IoffN + IoffP ) / 2 & ( 1 )\end{matrix}$$

FIG. 3 illustrates an example of a rise time Traise when the ON signal is output to the output terminal Y of the NOT type cell and an example of a fall time Tfall when the OFF signal is output to the output terminal Y of the NOT type cell. When the rise time Traise is short, a rising slope becomes steep, and when the rise time Traise is long, the rising slope becomes gentle. When the fall time Tfall is short, a falling slope becomes steep, and when the fall time Tfall is long, the falling slope becomes gentle.

As illustrated in FIG. 3, considering an operation speed in the NOT type cell, the rise time Traise is determined by an ON current value IonP of the p-type MOSFET, and is proportional to a load capacity Cload/IonP, where a circuit load is Cload. On the other hand, the fall time Tfall is determined by an ON current value IonN of the n-type MOSFET and is proportional to a load capacity Cload/IonN. The load capacity is a value, that is, the time obtained by dividing the circuit load Cload by the ON current. Here, an average circuit operation speed, that is, an average switching time Tpd can be represented by the following Expression (2).

$$\begin{matrix}[ Expression 2 ] & \\ Tpd = Tfall + Traise {}_{}^{\cdot } {=}_{\cdot }^{} Cload \cdot ( \frac{1}{IonN} + \frac{1}{IonP} ) & ( 2 )\end{matrix}$$

In general, many semiconductor device manufacturers have four types of design models for the gate threshold voltage Vt of the MOSFET. Specifically, as the gate threshold voltage Vt designed for the p-type MOSFET, there are a threshold voltage HVTP and a threshold voltage LVTP. An absolute value of the threshold voltage LVTP is lower than an absolute value of the threshold voltage HVTP. Further, as the gate threshold voltage Vt designed for the n-type MOSFET, there are a threshold voltage HVTN and a threshold voltage LVIN. An absolute value of the threshold voltage LVIN is lower than an absolute value of the threshold voltage HVTN.

Semiconductor device manufacturers design two types of logic gates having different balances between operation speed and leakage current by using the four types of gate threshold voltage design models. A first type of logic gate is a high-speed-operation/high-leakage-current type logic gate. A second type of logic gate is a low-speed-operation/low-leakage-current type logic gate.

The high-speed-operation/high-leakage-current type logic gate includes the p-type MOSFET having the threshold voltage LVTP and the n-type MOSFET having the threshold voltage LVIN. In the present specification, a cell which is the high-speed-operation/high-leakage-current type logic gate is also referred to as an LVT cell. Further, the low-speed-operation/low-leakage-current type logic gate includes the p-type MOSFET having the threshold voltage HVTP and the n-type MOSFET having the threshold voltage HVTN. In the present specification, a cell which is the low-speed-operation/low-leakage-current type logic gate is also referred to as an HVT cell.

As understood from FIG. 3, in general, as the absolute values of the gate threshold voltages Vt of the MOSFETS constituting the cell increase, that is, as the ON current of the cell decreases, a rise time and a fall time of a signal output Y of the cell become longer, and rising and falling become slower. Conversely, as the gate threshold voltages Vt of the FETs constituting the cell decrease, that is, as the ON current of the cell increases, the rise time and the fall time of the signal output Y of the cell become shorter, and rising and falling become faster. That is, as indicated by arrows SH31 and SH32 in FIG. 3, the rising slope and the falling slope of the signal output Y become steep. Further, when comparing the rise time of the p-type MOSFET and the fall time of the n-type MOSFET having ON currents equal to each other, the rise time of the p-type MOSFET is longer than the fall time of the n-type MOSFET.

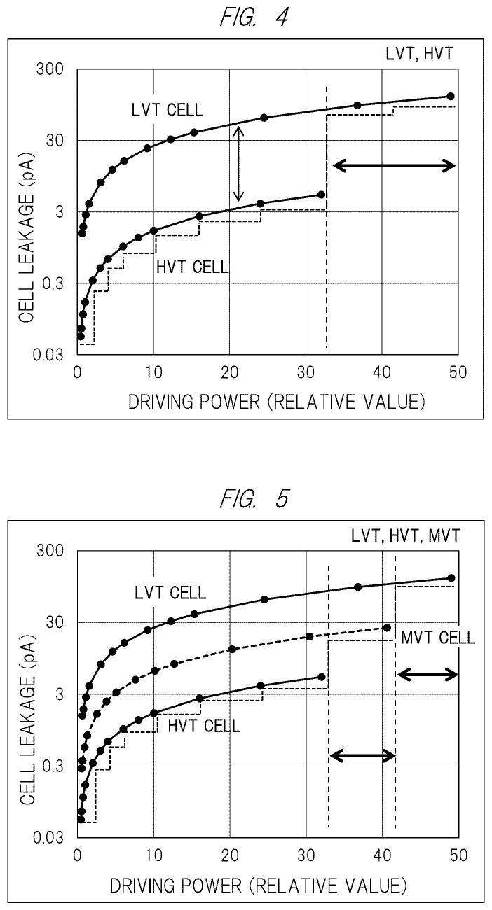

As illustrated in FIG. 4, when comparing the LVT cell and the HVT cell having the same driving powers, it can be seen that the cell leakage of the LVT cell is about 16 times the cell leakage of the HVT cell.

Semiconductor device manufacturers use the LVT cell in a portion for which high-speed operation is required, and use the HVT cell in a portion for which high-speed operation as fast as the LVT cell is not required. Accordingly, a semiconductor device is designed to minimize the cell leakage while ensuring a required operation speed.

However, in practice, a digital circuit portion, in which the high-speed-operation/high-leakage-current type LVT cell is used, includes a portion for which the operation speed is sufficient as a speed intermediate between the operation speed of the LVT cell and the operation speed of the HVT cell.

Therefore, as one of methods of further suppressing the power consumption while ensuring the operation speed, it is conceivable that the semiconductor device is designed to include a newly added MVT cell, the MVT cell having a characteristic in which a balance between the operation speed and the leakage current is intermediate between the LVT cell and the HVT cell.

As illustrated in FIG. 5, when comparing the LVT cell, the HVT cell, and the MVT cell having the same driving powers, it can be seen that the cell leakage of the MVT cell is located approximately in the middle of the cell leakage of the LVT cell and the cell leakage of the HVT cell.

To design the MVT cell, an intermediate threshold voltage MVTP is added as a design model of the gate threshold voltage of the p-type MOSFET, and an intermediate threshold voltage MVIN is added as a design model of the gate threshold voltage of the n-type MOSFET. An absolute value of the threshold voltage MVTP is higher than the absolute value of the threshold voltage LVTP and lower than the absolute value of the threshold voltage HVTP. Further, an absolute value of the threshold voltage MVIN is higher than the absolute value of the threshold voltage LVTN and lower than the absolute value of the threshold voltage HVTN. Then, the MVT cell is newly provided that is a combination of the p-type MOSFET having the threshold voltage MVTP and the n-type MOSFET having the threshold voltage MVTN.

Semiconductor device manufacturers selectively use three types of cells including the LVT cell, the HVT cell, and the MVT cell for each logic gate in the digital circuit portion of the semiconductor device according to the required operation speed. Here, the method is referred to as a standard method.

According to such a standard method, in the digital circuit portion of the semiconductor device, the MVT cell having the leakage current smaller than that of the LVT cell can be substituted for a portion of which the operation speed of the MVT cell is allowable among portions in which the LVT cells have been necessarily used. As a result, in the semiconductor device including the digital circuit, it is possible to suppress the power consumption compared to the semiconductor device in the related art while ensuring the required operation speed.

However, the standard method also has a problem. A process of manufacturing the semiconductor device includes a process of implanting impurities into a channel located immediately below a gate in a well in a semiconductor substrate. The process is also referred to as channel doping. The content of the process of channel doping differs depending on a difference in channel type (p-type/n-type) of the MOSFET and a difference in gate threshold voltage to be designed. In the process of channel doping, the gate threshold voltage of the MOSFET can be adjusted by adjusting the type, amount, or the state of diffusion of impurities to be implanted.

A mask is used in the process of channel doping. The mask has an opening corresponding to a region into which impurities are implanted. Therefore, to add the MVT cell as a cell to be used in the digital circuit, a mask for the p-type MOSFET having the threshold voltage MVTP and a mask for the n-type MOSFET having the threshold voltage MVTN are newly required. That is, when the MVT cell is added as a cell to be used in the digital circuit, the number of masks used for manufacturing increases, the number of manufacturing steps also increases, and financial and temporal costs increase.

The present inventors devised a method capable of further reducing power consumption while suppressing cost and ensuring required operation speed in the semiconductor device including the digital circuit.

### First Embodiment

A first embodiment is a semiconductor device including a digital circuit and a method of designing and manufacturing the semiconductor device. In the first embodiment, in the semiconductor device, in addition to the HVT cell and the LVT cell, a cell is used which has a characteristic intermediate between the HVT cell and the LVT cell and a configuration different from that of the MVT cell. Note that the HVT cell is an example of a “first cell” in the present application, and the LVT cell is an example of a “second cell” in the present application. Further, the cell which has a characteristic intermediate between the HVT cell and the LVT cell and a configuration different from that of the MVT cell is an example of a “third cell” in the present application. Furthermore, in each of the following embodiments, it is assumed that the thickness of a gate layer of the MOSFET constituting the cell is constant, and the size of the cell is proportional to the size of a well or the like occupying a substrate surface of a semiconductor substrate.

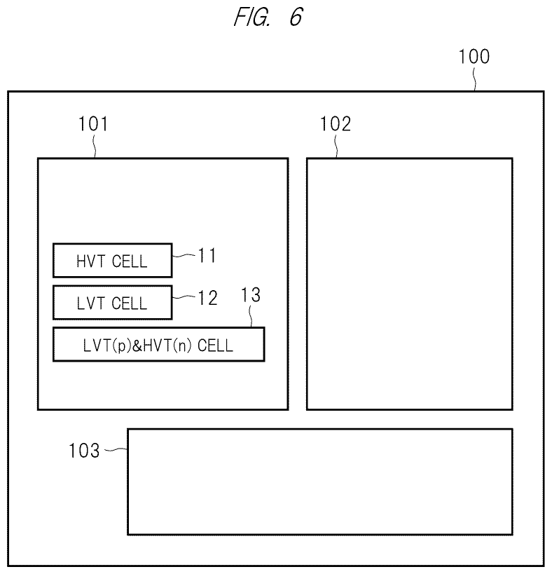

A semiconductor device 100 according to the first embodiment is, for example, an integrated circuit, and is a so-called semiconductor chip. As illustrated in FIG. 6, the semiconductor device 100 includes a digital circuit portion 101 and non-digital circuit portions 102 and 103. The non-digital circuit portion 102 is, for example, an analog circuit portion. The non-digital circuit portion 103 is, for example, an input/output (I/O) circuit portion.

Three types of cells are used in the digital circuit portion 101. That is, in addition to the HVT cell as the first cell and the LVT cell as the second cell which are used in the related art, the third cell is provided. Then, the digital circuit portion 101 is designed by combining the three types of cells.

The third cell includes a p-type MOSFET connected to a first potential and an n-type MOSFET connected to a second potential. The second potential is lower than the first potential. The threshold voltage Vt of the p-type MOSFET constituting the third cell is the threshold voltage LVTP which is the same as the threshold voltage of the p-type MOSFET constituting the LVT cell. Further, the threshold voltage Vt of the n-type MOSFET constituting the third cell is the threshold voltage HVTN which is the same as the threshold voltage of the n-type MOSFET constituting the HVT cell. That is, the third cell is characterized in that the threshold voltage of the p-type MOSFET is set as the threshold voltage LVTP which is relatively low for the p-type and the threshold voltage of the n-type MOSFET is set as the threshold voltage HVTN which is relatively high for the n-type.

Here, the threshold voltage HVTP is an example of a “first threshold voltage” in the present application, and the threshold voltage HVTN is an example of a “second threshold voltage” in the present application. Further, the threshold voltage LVTP is an example of a “third threshold voltage” in the present application, and the threshold voltage LVIN is an example of a “fourth threshold voltage” in the present application.

In general, a leakage current of an LVT cell constituted by a MOSFET having a threshold voltage Vt of a low absolute value corresponds to ten and several times to several tens of times a leakage current of an HVT cell constituted by a MOSFET having a threshold voltage Vt of a high absolute value. Further, due to physical properties of silicon, an ON current of an n-type MOSFET corresponds to about several times an ON current of a p-type MOSFET. Here, it is considered to compare a rise time of an output of the p-type MOSFET with a fall time of an output of the n-type MOSFET at the same ON current (load). Here, the rise time of the p-type MOSFET is longer than the fall time of the n-type MOSFET. The operation speed of the cell can be approximately considered as a reciprocal of the time required for switching constituted by rising and falling of the output of the cell.

Therefore, the threshold voltage Vt of the n-type MOSFET is set as the threshold voltage HVTN of which an absolute value is relatively high for the n-type, and the threshold voltage Vt of the p-type MOSFET is set as the threshold voltage LVTP of which an absolute value is relatively low of the p-type. As a result, the ON current of the p-type MOSFET is increased, and the rise time is shortened. According to such a design, it is possible to reduce the leakage current and increase the operation speed in the cell.

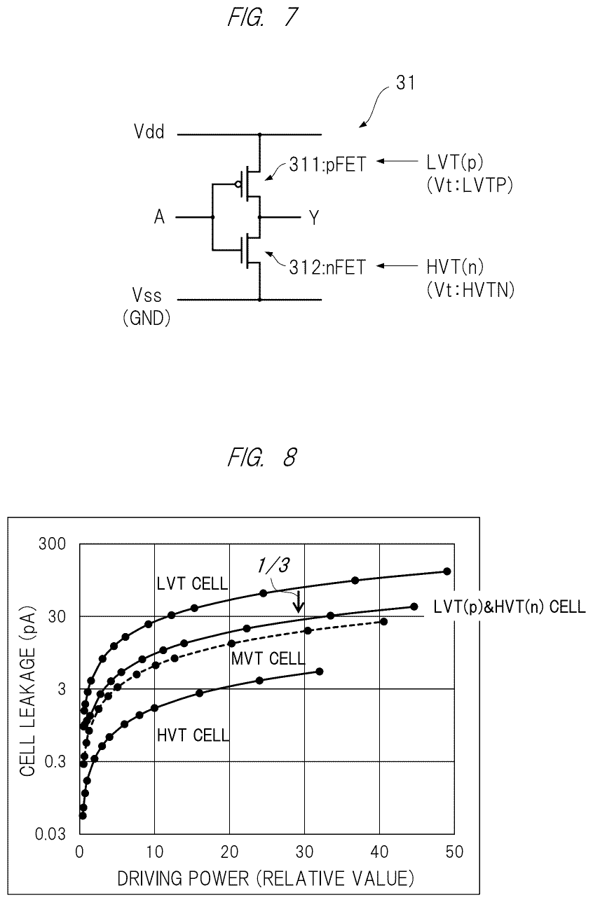

FIG. 7 illustrates a configuration example of a NOT (INV) type cell 31 which is an example of a logic gate. In the NOT type cell 31, a p-type MOSFET 311 connected to the line Vdd and an n-type MOSFET 312 connected to the line Vss (GND) are connected in series. The potential of the line Vdd is the first potential on the high potential side of the power supply, and the potential of the line Vss is the second potential on the low potential side of the same power supply. The gate of the p-type MOSFET 311 and the gate of the n-type MOSFET 312 are connected, and the connection point of the gates is the input terminal A. Further, the source of the p-type MOSFET 311 and the drain of the n-type MOSFET 312 are connected, and the connection point of the source and the drain is the output terminal Y.

In the NOT type cell 31, the p-type MOSFET 311 is a p-type MOSFET having the threshold voltage LVTP (hereinafter, also referred to as LVT(p)), and the n-type MOSFET 312 is an n-type MOSFET having the threshold voltage HVTN (hereinafter, also referred to as HVT(n)). In the present specification, a cell including the p-type MOSFET having the threshold voltage LVTP, that is, LVT(p), and the n-type MOSFET having the threshold voltage HVTN, that is, HVT(n), is referred to as an LVT(p)&HVT(n) cell.

FIG. 8 is a graph illustrating relationships between driving powers and cell leakages for each cell size for the LVT cell, the HVT cell, the LVT(p)&HVT(n) cell, and the MVT cell according to the standard method for comparison.

The driving power of the cell is correlated with the operation speed of the cell. Further, the cell leakage is correlated with the power consumption of the cell. That is, the higher the driving power, the higher the operation speed, and the smaller the cell leakage, the smaller the power consumption. As illustrated in FIG. 8, in the relationship between the driving power of the cell and the cell leakage, the LVT(p)&HVT(n) cell newly added in the first embodiment has a characteristic intermediate between the existing LVT cell and HVT cell, that is a characteristic close to the characteristic of the MVT cell according to the standard method. That is, the LVT(p)&HVT(n) cell can be used instead of the MVT cell.

That is, in the method of designing the digital circuit according to the first embodiment, the LVT(p)&HVT(n) cell is used in a portion for which the operation speed or the driving power intermediate between the LVT cell and the HVT cell is sufficient, among portions for which the operation speed or the driving power of the LVT cell is excessive but the operation speed or the driving power of the HVT cell is insufficient. Therefore, according to the first embodiment, it is possible to provide a digital circuit which reduces power consumption due to the leakage current while ensuring the required operation speed.

Further, in the method of designing the digital circuit according to the first embodiment, as the cell having the characteristic intermediate between the LVT cell and the HVT cell, the LVT(p)&HVT(n) cell is used instead of the MVT cell. Therefore, in the first embodiment, the design models of LVTP and HVTN, which are existing design models of the gate threshold voltages, can be intactly used to form the cell, and thus it is not necessary to newly develop new design models of the gate threshold voltages. Furthermore, in the first embodiment, it is not necessary to newly develop new design models of the gate threshold voltages. Therefore, a new mask is unnecessary and use of the existing mask is sufficient for the process of implanting impurities into the channel or the well in the semiconductor substrate for gate threshold voltage control during the process of manufacturing the digital circuit.

Further, according to the first embodiment, it is not necessary to newly develop design models of the gate threshold voltages. Furthermore, it is not necessary to manufacture a new mask as the mask used in the process of implanting impurities for gate threshold voltage control. Moreover, a process of using the new mask is also unnecessary. That is, according to the first embodiment, it is possible to realize the semiconductor device in which the balance between the operation speed and the power consumption is improved while suppressing the financial and time costs.

### <Estimation of Effect of Reducing Cell Leakage by Cell Replacement>

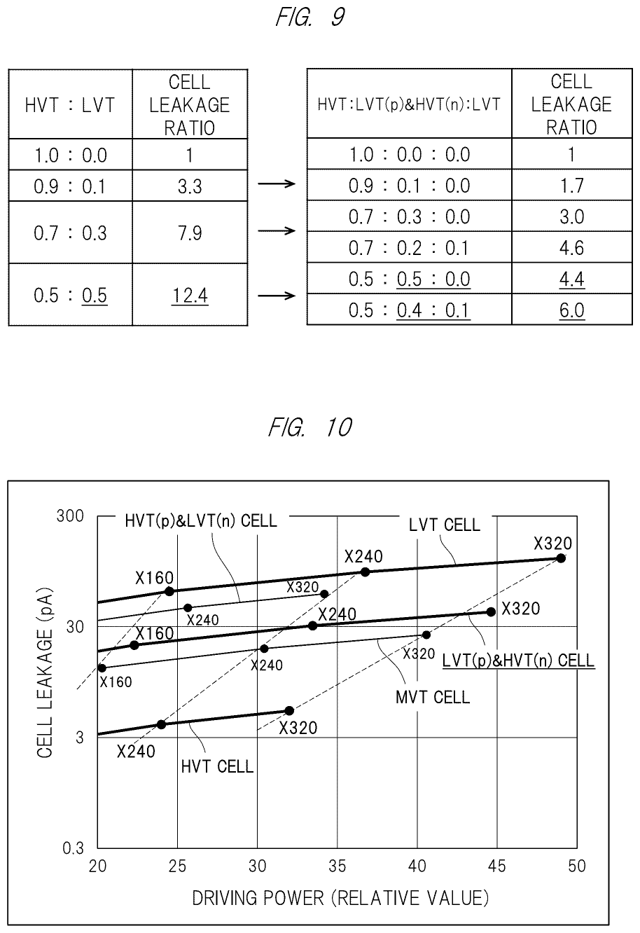

FIG. 9 illustrates a table illustrating a relationship between a usage ratio of types of cells and the cell leakage in the digital circuit. The table on the left side in FIG. 9 illustrates a relationship between a usage ratio of the HVT cell and the LVT cell and the cell leakage (related art example). The table on the right side in FIG. 9 illustrates a relationship between a usage ratio of the HVT cell, the LVT(p)&HVT(n) cell, and the LVT cell and the cell leakage in the digital circuit. Here, it is assumed that the cell sizes are all the same. Further, in the tables, the cell leakage is indicated as a cell leakage ratio which is a ratio when a cell leakage when all cells are HVT cells is set to 1.

For example, as illustrated in FIG. 9, in the related art example, when the usage ratio of the HVT cell and the LVT cell is 0.5:0.5, the cell leakage ratio is 12.4. On the other hand, in the example of the first embodiment, when the usage ratio of the HVT cell, the LVT(p)&HVT(n) cell, and the LVT cell is 0.5:0.5:0.0, the cell leakage ratio is 4.4. Further, in the example of the first embodiment, when the usage ratio of the HVT cell, the LVT(p)&HVT(n) cell, and the LVT cell is 0.5:0.4:0.1, the cell leakage ratio is 6.0. Therefore, in a case of a digital circuit in which the usage ratio of the HVT cell and the LVT cell is 0.5:0.5, the cell leakage can be reduced to about ½ times to about ⅓ times by replacing all or about 80% of the LVT cells with the LVT(p)&HVT(n) cells.

<Relationship between Driving Power and Leakage Current of Cell>

FIG. 10 is a graph illustrating a relationship between the driving power and the cell leakage of the LVT cell, the HVT cell, the MVT cell, and the LVT(p)&HVT(n) cell. Further, in the graph illustrated in FIG. 10, a curve (close to a straight line) is drawn by a broken line for each cell size, in which the curve represents characteristics when the threshold voltages Vt of both the p-type MOSFET and the n-type MOSFET are simultaneously adjusted in the same positive or negative direction in the cells having the same size. Note that, in the graph illustrated in FIG. 10, “X160”, “X240”, and “X320” represent cell sizes, and the larger the number, the larger the cell size. The physical heights of the MOSFETs constituting the cells are the same, and the occupied areas of the cells are different.

As illustrated in FIG. 10, a ratio of the cell leakage to the driving power in the HVT cell is relatively small. A ratio of the cell leakage to the driving power in the LVT cell is relatively large. A ratio of the cell leakage to the driving power in the MVT cell is characterized to be intermediate between the HVT cell and the LVT cell. A ratio of the cell leakage to the driving power in the LVT(p)&HVT(n) cell is slightly greater than the ratio of the MVT cell, and has a characteristic close to the ratio of the MVT cell.

Here, in the graph illustrated in FIG. 10, the curve corresponding to the LVT(p)&HVT(n) cell is compared with each of the curves corresponding to the HVT cell, the LVT cell, and the MVT cell. Then, it can be seen that the curve corresponding to the LVT(p)&HVT(n) cell is generally shifted to the right side from the other curves. This means that the cell leakage to the driving power in the LVT(p)&HVT(n) cell is smaller than that in other cells. That is, when cells having the same size and the same driving power are compared with each other, it can be seen that the cell leakage of the LVT(p)&HVT(n) cell is less than the cell leakage of other cells and the LVT(p)&HVT(n) cell has higher performance than the MVT cell.

<Relationship between Operation Speed and Leakage Current of Cell>

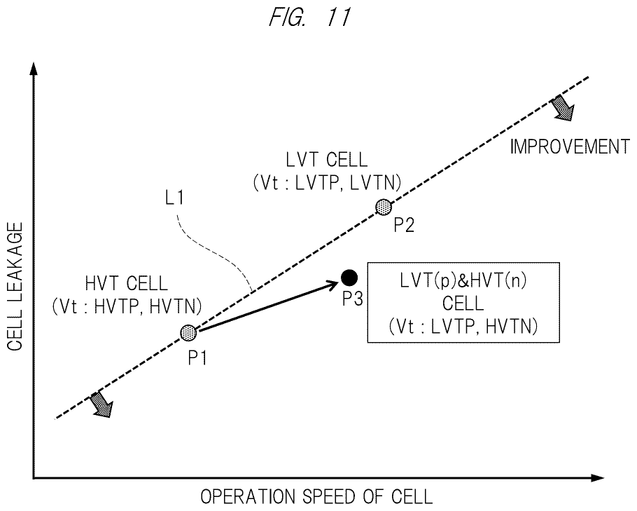

FIG. 11 is a graph illustrating a relationship between the operation speed and the cell leakage for each cell. In the graph illustrated in FIG. 11, a plot P1 indicates the relationship between the operation speed and the cell leakage in the HVT cell. A plot P2 indicates the relationship between the operation speed and cell leakage in the LVT cell. Further, a plot P3 indicates the relationship between the operation speed and the cell leakage in the LVT(p)&HVT(n) cell. Furthermore, in the graph illustrated in FIG. 11, a curve (close to a straight line) L1 indicating the relationship between the operation speed and the cell leakage is drawn by a broken line regarding a cell formed by simultaneously changing the threshold voltages Vt of the n-type FET and the p-type FET. In the graph illustrated in FIG. 11, a region below the broken line L1 (obliquely lower right) indicates a region where the balance between the operation speed and the cell leakage is further improved.

In the graph illustrated in FIG. 11, the plot P3 corresponding to the LVT(p)&HVT(n) cell is located below the broken line L1. Therefore, the LVT(p)&HVT(n) cell not only has a characteristic intermediate between the LVT cell and the HVT cell, but also has an improved balance between the operation speed and the cell leakage as compared with the LVT cell and the HVT cell. This is also a feature of the LVT cell and the HVT cell different from a feature of the MVT cell.

### <Method of Manufacturing Cell>

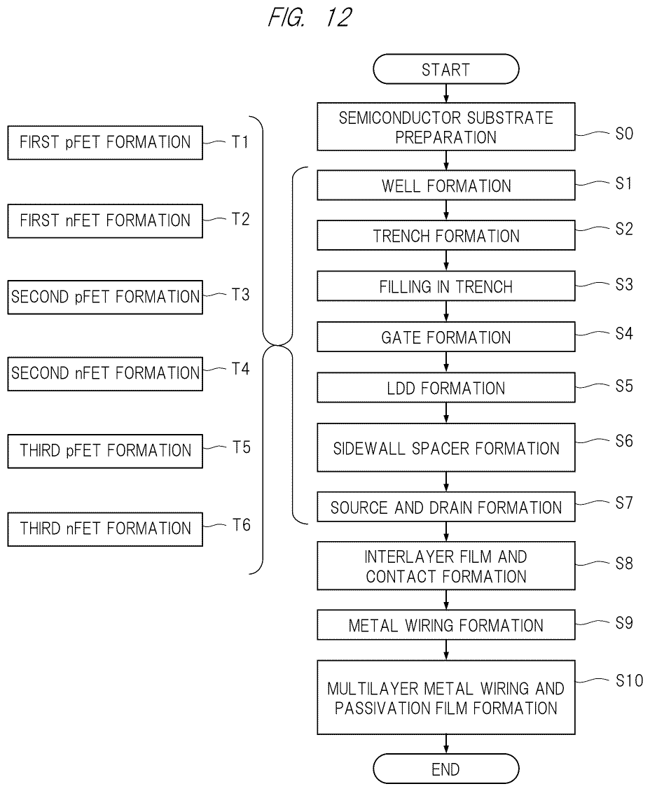

As illustrated in FIG. 12, in Step (process) S0, a process of preparing a semiconductor substrate is performed. In Step S1, a process of forming a well is performed. Note that details of the process of forming the well in Step S1 will be described later. In Step S2, a process of forming a trench is performed. In Step S3, a process of filling the trench is performed. In Step S4, a process of forming a gate is performed. Note that details of the process of forming the gate in Step S4 will be described later.

In Step S5, a process of forming a lightly doped drain (LDD) is performed. In Step S6, a process of forming a sidewall spacer is performed. In Step S7, a process of forming a source and a drain is performed. In Step S8, a process of forming an interlayer film and a contact is performed. In Step S9, a process of forming a metal wiring is performed. In Step S10, a process of wiring a multilayer metal and a process of forming a passivation film are performed.

Note that, as illustrated in FIG. 12, performing processes of Steps S1 to S7 described above is substantially equivalent to performing processes of Steps T1 to T6 described below. Step T1 is a process of forming a first p-type MOSFET of the HVT cell. Step T2 is a process of forming a first n-type MOSFET of the HVT cell. Step T3 is a process of forming a second p-type MOSFET of the HVT cell. Step T4 is a process of forming a second n-type MOSFET of the HVT cell. Step T5 is a process of forming a third p-type MOSFET of the LVT(p)&HVT(n) cell. Step T6 is a process of forming a third n-type MOSFET of the LVT(p)&HVT(n) cell.

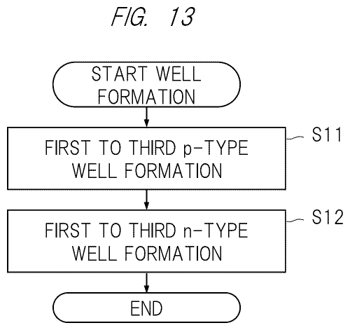

As illustrated in FIG. 13, in Step S11, a first p-type well, a second p-type well, and a third p-type well are formed by implanting p-type impurities into a semiconductor substrate 10. Further, in Step S12, a first n-type well, a second n-type well, and a third n-type well are formed by implanting n-type impurities into the semiconductor substrate 10.

Here, the first p-type well is a well of an n-type MOSFET constituting the HVT cell. The second p-type well is a well of an n-type MOSFET constituting the HVT cell. The third p-type well is a well of an n-type MOSFET constituting the LVT(p)&HVT(n) cell. Further, the first n-type well is a well of a p-type MOSFET constituting the HVT cell. The second n-type well is a well of a p-type MOSFET constituting the HVT cell. The third n-type well is a well of a p-type MOSFET constituting the LVT(p)&HVT(n) cell.

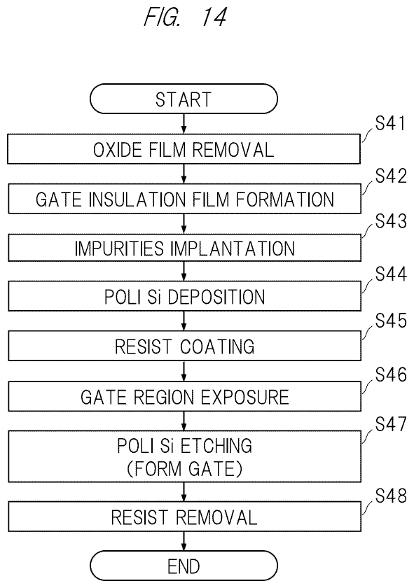

Next, as illustrated in FIG. 14, in Step S41, an element isolation structure is formed. First, a trench is formed in the semiconductor substrate, and an oxide film is formed on the semiconductor substrate to fill the trench. Thereafter, the oxide film formed outside the trench is removed to form the element isolation structure.

In Step S42, a process of forming a gate insulation film is performed. For example, the gate insulation film (oxide film) is formed by oxidizing the semiconductor substrate. As a result, the first p-type MOSFET and the first n-type MOSFET constituting a HVT cell 11 as the first cell have a first gate insulation film. Further, the second p-type MOSFET and the second n-type MOSFET constituting an LVT cell 12 as the second cell have a second gate insulation film. Furthermore, the third p-type MOSFET and the third n-type MOSFET constituting an LVT(p)&HVT(n) cell 13 as the third cell have a third gate insulation film. In addition, a thickness of the first gate insulation film, a thickness of the second gate insulation film, and a thickness of the third gate insulation film are the same. However, by describing that the thicknesses of the gate insulation films are the same does not mean that the thicknesses are exactly the same, but means that the thicknesses are the same in design, thereby allowing manufacturing errors and the like.

In Step S43, a process of implanting impurities for threshold voltage adjustment is performed. Specifically, three types of cells are laid out on the semiconductor substrate. For each type of individual cell, impurities are implanted into the channel located immediately below the gate in the well to adjust the threshold voltage of each of the p-type MOSFET and the n-type MOSFET constituting the cell. The threshold voltage is adjusted by changing an amount of impurities to be implanted, a concentration of impurities in the channel, a degree of diffusion, and the like. p-type impurities are implanted into the channel in the p-type well in the n-type MOSFET. n-type impurities are implanted into the channel in the n-type well in the p-type MOSFET. Examples of the n-type impurities include phosphorus (P), arsenic (As), antimony (Sb), and the like. Examples of the p-type impurities include boron (B), indium (In), aluminum (Al), and the like.

In the present example, each MOSFET of each cell has a channel having an impurity concentration as described below by performing the process of implanting impurities for threshold voltage adjustment.

The first p-type MOSFET constituting the HVT cell 11 as the first cell has a channel having a first impurity concentration corresponding to the threshold voltage HVTP. Further, the first n-type MOSFET constituting the HVT cell 11 as the first cell has a channel having a second impurity concentration corresponding to the threshold voltage HVTN.

The second p-type MOSFET constituting the LVT cell 12 as the second cell has a channel having a third impurity concentration corresponding to the threshold voltage LVTP. Further, the second n-type MOSFET constituting the LVT cell 12 as the second cell has a channel having a fourth impurity concentration corresponding to the threshold voltage LVTN.

The third p-type MOSFET constituting the LVT(p)&HVT(n) cell 13 as the third cell has a channel having the third impurity concentration corresponding to the threshold voltage LVTP. Further, the third n-type MOSFET constituting the LVT(p)&HVT(n) cell 13 as the third cell has a channel having the second impurity concentration corresponding to the threshold voltage HVTN.

Note that, when the impurity concentration in the channel of the MOSFET increases, the absolute value of the threshold voltage of the MOSFET increases. Conversely, when the impurity concentration in the channel of the MOSFET decreases, the absolute value of the threshold voltage of the MOSFET decreases.

Therefore, in the p-type MOSFET, the impurity concentration in the channel of the first n-type well corresponding to the threshold voltage HVTP is higher than the impurity concentration in the channel of the second n-type well and the impurity concentration in the channel of the third n-type well corresponding to the threshold voltage LVTP. Further, in the n-type MOSFET, the impurity concentration in the channel of the first p-type well and the impurity concentration in the channel of the third p-type well corresponding to the threshold voltage HVTN is higher than the impurity concentration in the channel of the second p-type well corresponding to the threshold voltage LVTN.

In the n-type MOSFET, the impurity concentration in the channel of the first p-type well corresponding to the threshold voltage HVTN is the same as the impurity concentration in the channel of the third p-type well corresponding to the threshold voltage HVTN. Further, in the p-type MOSFET, the impurity concentration in the channel of the second n-type well corresponding to the threshold voltage LVTP is the same as the impurity concentration in the channel of the third n-type well corresponding to the threshold voltage LVTP. Note that, the fact that the impurity concentrations are the same means that the designed concentrations are the same, and errors that occur in actual manufacturing are allowed.

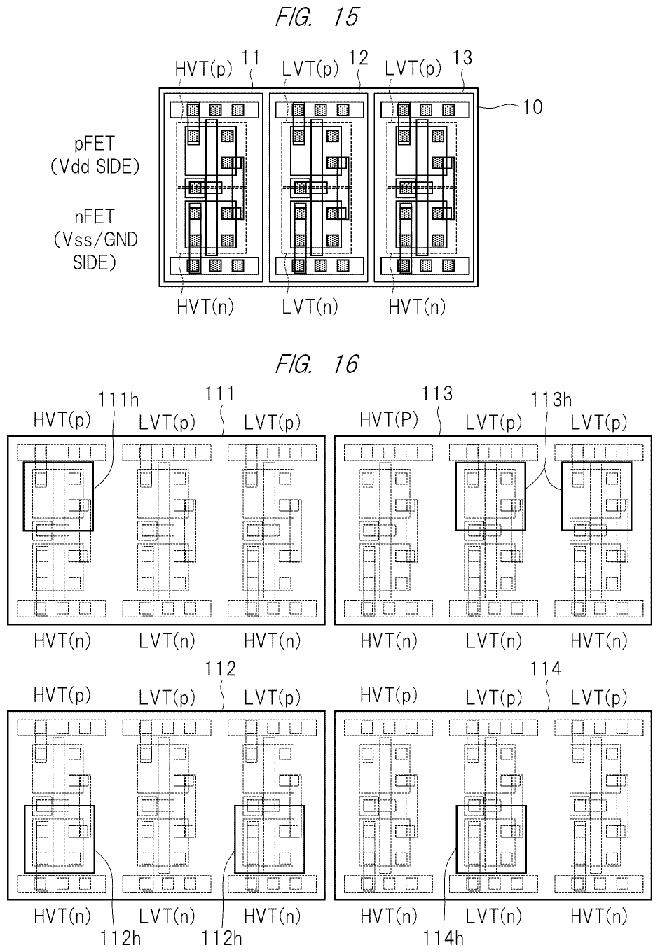

Here, for example, as illustrated in FIG. 15, a design in which the HVT cell 11, the LVT cell 12, and the LVT(p)&HVT(n) cell 13 are laid out on the semiconductor substrate 10 is considered. The HVT cell 11 includes the p-type MOSFET having the threshold voltage HVTP and the n-type MOSFET having the threshold voltage HVTN. The LVT cell 12 includes the p-type MOSFET having the threshold voltage LVTP and the n-type MOSFET having the threshold voltage LVTN. Further, the LVT(p)&HVT(n) cell 13 includes the p-type MOSFET having the threshold voltage LVTP and the n-type MOSFET having the threshold voltage HVTN.

The type of impurities to be implanted in the p-type MOSFET is different from the type of impurities to be implanted in the n-type MOSFET. That is, conditions of implantation of impurities corresponding to the threshold voltage HVTP and the threshold voltage LVTP are different from conditions of implantation of impurities corresponding to the threshold voltage HVTN and the threshold voltage LVIN. Further, even when the same p-type MOSFETs or the same n-type MOSFETs are compared with each other, magnitudes of the absolute values of the threshold voltages to be adjusted may be different, and thus amounts of implantation or states of diffusion of impurities are different and the conditions of implantation of impurities are different. Therefore, in Step S43, four types of masks are used.

Specifically, as illustrated in FIG. 16, the above-mentioned four types of masks include a mask 111 for the threshold voltage HVTP, a mask 112 for the threshold voltage HVTN, a mask 113 for the threshold voltage LVTP, and a mask 114 for the threshold voltage LVTN.

As illustrated in FIG. 16, the mask 111 for the threshold voltage HVTP covers the wells of the MOSFETs to have the threshold voltage HVTN, the threshold voltage LVTP, and the threshold voltage LVTN, and has an opening 111h to expose the channel of the p-type MOSFET to have the threshold voltage HVTP. Specifically, the mask 111 for the threshold voltage HVTP covers the wells of the n-type MOSFET of the HVT cell 11, the p-type MOSFET and the n-type MOSFET of the LVT cell 12, and the p-type MOSFET and the n-type MOSFET of the LVT(p)&HVT(n) cell 13, and is formed to expose the channel of the p-type MOSFET of the HVT cell 11.

As illustrated in FIG. 16, the mask 112 for the threshold voltage HVTN covers the wells of the MOSFETs to have the threshold voltage HVTP, the threshold voltage LVTP, and the threshold voltage LVTN, and has an opening 112h to expose the channel of the n-type MOSFET to have the threshold voltage HVTN. Specifically, the mask 112 for the threshold voltage HVTN covers the wells of the p-type MOSFET of the HVT cell 11, the p-type MOSFET and the n-type MOSFET of the LVT cell 12, and the p-type MOSFET of the LVT(p)&HVT(n) cell 13, and is formed to expose the channels of the n-type MOSFET of the HVT cell 11 and the n-type MOSFET of the LVT(p)&HVT(n) cell 13.

As illustrated in FIG. 16, the mask 113 for the threshold voltage LVTP covers the wells of the MOSFETs to have the threshold voltage HVTP, the threshold voltage HVTN, and the threshold voltage LVIN, and has an opening 113h to expose the channel of the p-type MOSFET to have the threshold voltage LVTP. Specifically, the mask 113 for the threshold voltage LVTP covers the wells in the p-type MOSFET and the n-type MOSFET of the HVT cell 11, the n-type MOSFET of the LVT cell 12, and the n-type MOSFET of the LVT(p)&HVT(n) cell 13, and is formed to expose the channels of the p-type MOSFET of the LVT cell 12 and the p-type MOSFET of the LVT(p)&HVT(n) cell 13.

As illustrated in FIG. 16, the mask 114 for the threshold voltage LVTN covers the wells of the MOSFETs to have the threshold voltage HVTP, the threshold voltage HVTN, and the threshold voltage LVTP, and has an opening 114h to expose the channel of the n-type MOSFET to have the threshold voltage LVTN. Specifically, the mask 114 for the threshold voltage LVIN covers the wells in the p-type MOSFET and the n-type MOSFET of the HVT cell 11, the p-type MOSFET of the LVT cell 12, and the p-type MOSFET and the n-type MOSFET of the LVT(p)&HVT(n) cell 13, and is formed to expose the channel of the n-type MOSFET of the LVT cell 12.

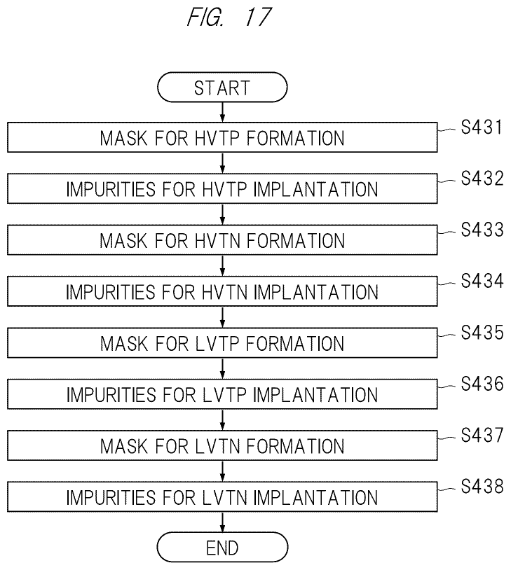

As illustrated in FIG. 17, first, in Step S431, the mask 111 for the threshold voltage HVTP is formed (disposed) on the semiconductor substrate 10. Thereafter, in Step S432, a process of implanting the n-type impurities for the threshold voltage HVTP into the channel of the n-type well corresponding to the threshold voltage HVTP in the semiconductor substrate 10 is performed using the mask 111 for the threshold voltage HVTP. Here, the “mask for the threshold voltage HVTP” is an example of a “first mask film” in the present application. Further, the “n-type well corresponding to the threshold voltage HVTP” is an example of a “first n-type well” in the present application.

Next, in Step S433, the mask 112 for the threshold voltage HVTN is formed (disposed) on the semiconductor substrate 10. Thereafter, in Step S434, a process of implanting the p-type impurities for the threshold voltage HVTN into the channel of the p-type well corresponding to the threshold voltage HVTN in the semiconductor substrate 10 is performed using the mask 112 for the threshold voltage HVTN. Here, the “mask for the threshold voltage HVTN” is an example of a “second mask film” in the present application. Further, the “p-type well corresponding to the threshold voltage HVTN” is an example of a “first p-type well” and an example of a “third p-type well” in the present application.

Next, in Step S435, the mask 113 for the threshold voltage LVTP is formed (disposed) on the semiconductor substrate 10. Thereafter, in Step S436, a process of implanting the n-type impurities for the threshold voltage LVTP into the channel of the n-type well corresponding to the threshold voltage LVTP in the semiconductor substrate 10 is performed using the mask 113 for the threshold voltage LVTP. Here, the “mask for the threshold voltage LVTP” is an example of a “third mask film” in the present application. Further, the “n-type well corresponding to the threshold voltage LVTP” is an example of a “second n-type well” and an example of a “third n-type well” in the present application.

Next, in Step S437, the mask 114 for the threshold voltage LVTN is formed (disposed) on the semiconductor substrate 10. Thereafter, in Step S438, a process of implanting the p-type impurities for the threshold voltage LVIN into the channel of the p-type well corresponding to the threshold voltage LVIN in the semiconductor substrate 10 is performed using the mask 114 for the threshold voltage LVTN. Here, the “mask for the threshold voltage LVTN” is an example of a “fourth mask film” in the present application. Further, the “p-type well corresponding to the threshold voltage LVTN” is an example of a “second p-type well” in the present application.

Here, Step S431 and Step S432 performed after Step S431 are defined as a process A. Step S433 and Step S434 performed after Step S433 are defined as a process B. Step S435 and Step S436 performed after Step S435 are defined as a process C. Further, Step S437 and Step S438 performed after Step S437 is defined as a process D. As described above, the example in which the process A, the process B, the process C, and the process D are performed in this order has been described, but the order in which the processes A to D are performed is not limited thereto. For example, the process A, the process C, the process B, and the process D may be performed in this order, or the process D, the process C, the process B, and the process A may be performed in this order.

Further, when the digital circuit using the HVT cell 11, the LVT cell 12, and the LVT(p)&HVT(n) cell 13 is formed by the method according to the first embodiment, to implant impurities for threshold voltage adjustment, as described above, four masks are sufficient as in the related art. On the other hand, when the digital circuit using the HVT cell 11, the LVT cell 12, and the MVT cell is formed by the standard method, to implant impurities for threshold voltage adjustment, two masks including the mask for the threshold voltage MVTP and the mask for the threshold voltage MVIN are further required, and a total of six masks are required.

### Effects of First Embodiment

According to the first embodiment, by replacing at least a part of the LVT cell with the LVT(p)&HVT(n) cell in the digital circuit portion of the semiconductor device, it is possible to reduce the cell leakage, that is, power consumption while ensuring the required operation speed in the digital circuit portion. Further, according to the first embodiment, the operation speed of the cell can be improved under the condition that the cell leakage is the same as compared with the cell according to the standard method.

Further, according to the first embodiment, when forming the semiconductor device including the digital circuit portion, it is unnecessary to add masks to be used for implantation of impurities as compared with the standard method. Therefore, there is no increase in manufacturing cost of the added mask and in the process of implanting impurities, and the cost can be suppressed.

Further, according to the first embodiment, by lowering the absolute value of the gate threshold voltages Vt for only the p-type MOSFETs, the driving power of the cell is improved under the condition that the OFF leakage is the same. Furthermore, as understood from FIG. 10, the LVT(p)&HVT(n) cell becomes a cell having a lower leakage and a higher driving power than the MVT cell. Moreover, as understood from FIG. 3, the LVT(p)&HVT(n) cell has the highest driving power ratio to cell leakage in any cell size.

Further, according to the first embodiment, the three types of cells according to the first embodiment can be selectively used in the digital circuit portion of the semiconductor device including the digital circuit portion and the non-digital circuit portion according to the required operation speed or driving power. As a result, it is possible to provide a semiconductor device in which power consumption is suppressed while ensuring the required operation speed. Consequently, according to the first embodiment, it is possible to improve the balance between the operation speed and the power consumption in the semiconductor device including the digital circuit.

### Second Embodiment

A second embodiment is a modification of the LVT(p)&HVT(n) cell according to the first embodiment. In the second embodiment, the threshold voltage Vt is changed without changing the relative magnitude relationship of the absolute values of the threshold voltages Vt in the p-type MOSFETs and the n-type MOSFETS constituting the cell.

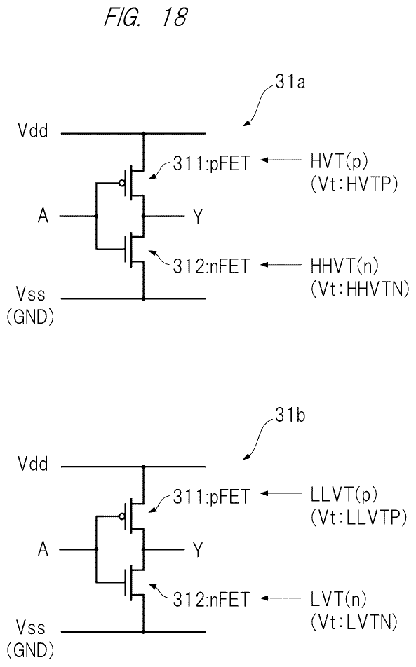

A NOT (INV) type cell 31a illustrated in FIG. 18 represents an HVT(p)&HHVT(n) cell formed by a combination of the p-type MOSFET having the threshold voltage HVTP and an n-type MOSFET having a threshold voltage HHVTN. An absolute value of the threshold voltage HHVTN is greater than the absolute value of the threshold voltage HVTN. Such an HVT(p)&HHVT(n) cell has a lower OFF leakage and a higher operation speed than the LVT(p)&HVT(n) cell. The HVT(p)&HHVT(n) cell is suitable, for example, as a cell to be used in a circuit portion for which the required operation speed is not as high as the operation speed of the LVT cell but is insufficient with the operation speed of the LVT(p)&HVT(n) cell. The “threshold voltage HHVTN” is an example of a “fifth threshold voltage” in the present application.

A NOT (INV) type cell 31b illustrated in FIG. 18 represents an LLVT(p)&LVT(n) cell formed by combining a p-type MOSFET having a threshold voltage LLVTP and the n-type MOSFET having the threshold voltage LVTN. The absolute value of the threshold voltage LVIN is greater than an absolute value of the threshold voltage LLVTN. Such an LLVT(p)&LVT(n) cell has a lower OFF leakage and a higher operation speed than the LVT(p)&HVT(n) cell. The LLVT(p)&LVT(n) cell is suitable, for example, as a cell to be used in a circuit portion for which the required operation speed is not as high as the operation speed of the LVT cell but is insufficient with the operation speed of the LVT(p)&HVT(n) cell.

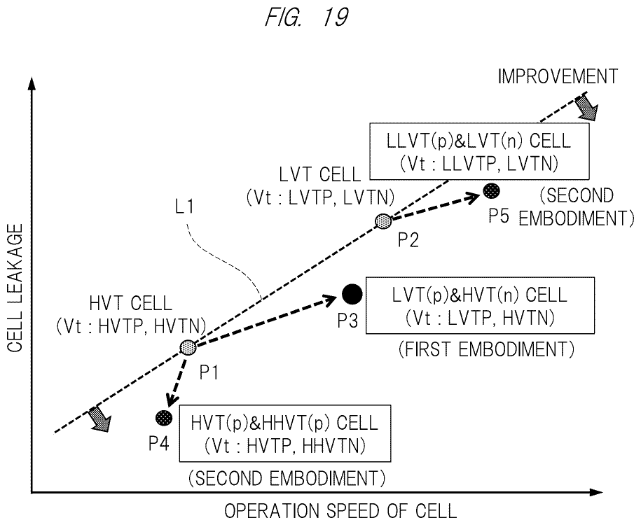

FIG. 19 illustrates a graph in which a plot P1 and a plot P2 are drawn, the plot P1 illustrating a relationship between the operation speed and the cell leakage corresponding to the HVT cell and the plot P2 illustrating a relationship between the operation speed and the cell leakage corresponding to the LVT cell. Further, in the graph illustrated in FIG. 19, a plot P3 is drawn, which illustrates a relationship between the operation speed and the cell leakage corresponding to the LVT(p)&HVT(n) cell. Furthermore, in the graph illustrated in FIG. 19, a plot P4 and a plot P5 are drawn, the plot P4 illustrating a relationship between the operation speed and the cell leakage corresponding to the HVT(p)&HHVT(n) cell and the plot P5 illustrating a relationship between the operation speed and the cell leakage corresponding to the LLVT(p)&LVT(n) cell. In addition, in the graph illustrated in FIG. 19, a curve (close to a straight line) L1 is drawn by a broken line, which indicates a relationship between the operation speed and the cell leakage in a cell formed by simultaneously changing the threshold voltages Vt of the n-type MOSFET and the p-type MOSFET. In the graph illustrated in FIG. 19, a region below the broken line L1 (obliquely lower right) indicates a region where the balance between the operation speed and the cell leakage is further improved.

As understood from the graph illustrated in FIG. 19, the HVT(p)&HHVT(n) cell and the LLVT(p)&LVT(n) cell are located below the broken line L1. Thus, similarly to the LVT(p)&HVT(n) cell, the HVT(p)&HHVT(n) cell and LLVT(p)&LVT(n) cell have an improved balance between the operation speed and the cell leakage as compared with the LVT cell and the HVT cell. The HVT(p)&HHVT(n) cell is suitable, for example, as compared with the HVT cell, as a cell to be used in a portion for which the reduction of cell leakage is more important than the operation speed of the cell. On the other hand, the LLVT(p)&LVT(n) cell is suitable as, for example, a cell to be used in a portion for which the operation speed of the cell is more important than the reduction of cell leakage as compared with the LVT cell. The “threshold voltage LLVTN” is an example of a “sixth threshold voltage” in the present application.

Note that, when the HVT(p)&HHVT(n) cell is manufactured in addition to the two types of cells according to the related art or the three types of cells according to the first embodiment, a mask for HHVT is newly required (a total of five masks are required). Further, when the LLVT(p)&LVT(n) cell is newly manufactured in addition to the two types of cells according to the related art or the three types of cells according to the first embodiment, a mask for LLVT is newly required (a total of five masks are required). However, in either case of the HVT(p)&HHVT(n) cell and the LLVT(p)&LVT(n) cell, the number of masks is incremented by one. That is, it is not necessary to add two new masks as in the case of the MVT cell (a total of six masks are required).

### Third Embodiment

A third embodiment is an example in which not only the LVT cell but also the LVT(p)&HVT(n) cell is used in a combination circuit, for which a relatively high-speed operation is required, among combination circuits connected between flip-flop circuits.

Generally, there are various kinds of time delays caused in the combination circuit. In the related art, a combination circuit which has a relatively large delay or for which a short delay is required among combination circuits is required to use a cell which operates at a high speed. Therefore, in the related art, in a combination circuit for which such a short delay is required, a cell having a high operation speed but a large leakage current has to be used. That is, in such a circuit, it is necessary to use a cell having a high driving power. Specifically, among the HVT cell 11 and the LVT cell 12, it is necessary to use the LVT cell 12 having a high-speed operation and a high driving power.

On the other hand, in the third embodiment, the LVT(p)&HVT(n) cell 13 having a medium speed operation and a medium driving power is used in a combination circuit for which the operation speed and the driving power in the LVT(p)&HVT(n) cell 13 are sufficient, among combination circuits for which such short delays are required. Accordingly, in the combination circuit, it is possible to suppress the leakage current while ensuring the required operation speed. Hereinafter, the third embodiment will be described with reference to the drawings.

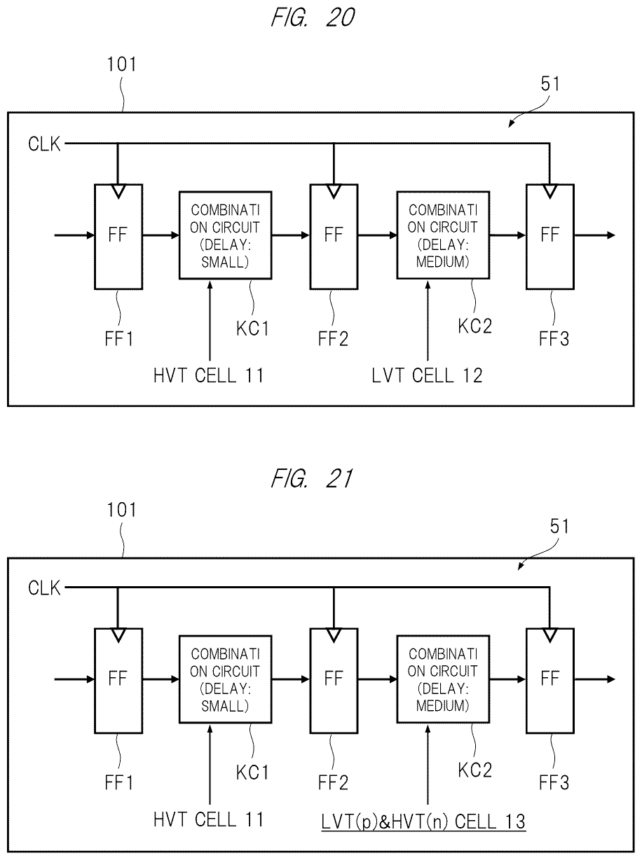

FIG. 20 illustrates a configuration example of the combination circuit according to the related art, and FIG. 21 illustrates a configuration example of the combination circuit according to the third embodiment. Note that, in FIGS. 20 and 21, the flip-flop circuit is represented by “FF”.

As illustrated in FIGS. 20 and 21, some circuits 51 included in the digital circuit portion 101 each include a first flip-flop circuit FF1, a second flip-flop circuit FF2, a third flip-flop circuit FF3, a first combination circuit KC1, and a second combination circuit KC2. The first flip-flop circuit FF1, the second flip-flop circuit FF2, and the third flip-flop circuit FF3 operate in synchronization with the same clock signal CLK. The first combination circuit KC1 is connected between the first flip-flop circuit FF1 and the second flip-flop circuit FF2. The second combination circuit KC2 is connected between the second flip-flop circuit FF2 and the third flip-flop circuit FF3.

Here, to simplify the description, the time delay caused by the operation of the combination circuit is represented in three stages of large, medium, and small, and the required operation speed is represented in three stages of high, medium, and low. The delay caused in the first combination circuit KC1 is small, and the required operation speed is low. The delay caused in the second combination circuit KC2 is medium, and the required operation speed is medium. Further, the operation speed of the cell is represented in three stages of high, medium, and low. Here, the operation speed of the HVT cell 11 is low, the operation speed of the LVT cell 12 is low, and the operation speed of the LVT(p)&HVT(n) cell 13 is medium.

FIG. 20 illustrates an example in which the HVT cell 11 and the LVT cell 12 according to the related art are used in the combination circuit. Further, FIG. 21 illustrates an example in which the HVT cell 11 and the LVT(p)&HVT(n) cell 13 are used in the combination circuit.

In the related art, as illustrated in FIG. 20, the HVT cell 11 having a low operation speed is used in the first combination circuit KC1 having a small delay and a low required operation speed. Further, the LVT cell 12 having a high operation speed has to be used in the second combination circuit KC2 of which the delay is medium and the required operation speed is medium.

On the other hand, in the third embodiment, as illustrated in FIG. 21, the HVT cell 11 having a low operation speed is used in the first combination circuit KC1 having a small delay and a low required operation speed. Meanwhile, the LVT(p)&HVT(n) cell 13 in which the operation speed is medium is used in the second combination circuit KC2 of which the delay is medium and the required operation speed is medium.

That is, the LVT cell 12 that operates at a high speed is used in a combination circuit of which the caused time delay is relatively large (for example, the wiring is physically long, or the number of circuits is large), among the combination circuits connected between the flip-flop circuits. The LVT(p)&HVT(n) cell 13 is used in a combination circuit of which the caused delay is medium and the operation speed of the LVT(p)&HVT(n) cell 13 is sufficient. The low-speed HVT cell 11 is used in a combination circuit of which the caused delay is small and the operation speed of the LVT(p)&HVT(n) cell 13 is excessive.

As described above, in the third embodiment, the medium-speed and medium-leakage LVT(p)&HVT(n) cell 13 is used instead of the high-speed and large-leakage LVT cell in the second combination circuit KC2 that requires a medium operation speed. Therefore, according to the third embodiment, in the digital circuit including the flip-flop circuit and the combination circuit, it is possible to reduce the cell leakage while ensuring the required operation speed.

In the above-mentioned specific example, the cells are selectively used based on the required operation speed, but the cells may be selectively used based on the required driving power. For example, the LVT cell 12 having a high driving power may be used in a portion where the required driving power is high, the HVT cell 11 having a small driving power may be used in a portion where the required driving power is small, and the LVT(p)&HVT(n) cell 13 having a medium driving power may be used in a portion where the required driving power is medium.

### Fourth Embodiment

A fourth embodiment is an example of a NAND circuit type cell to be used in the digital circuit portion included in the semiconductor device.

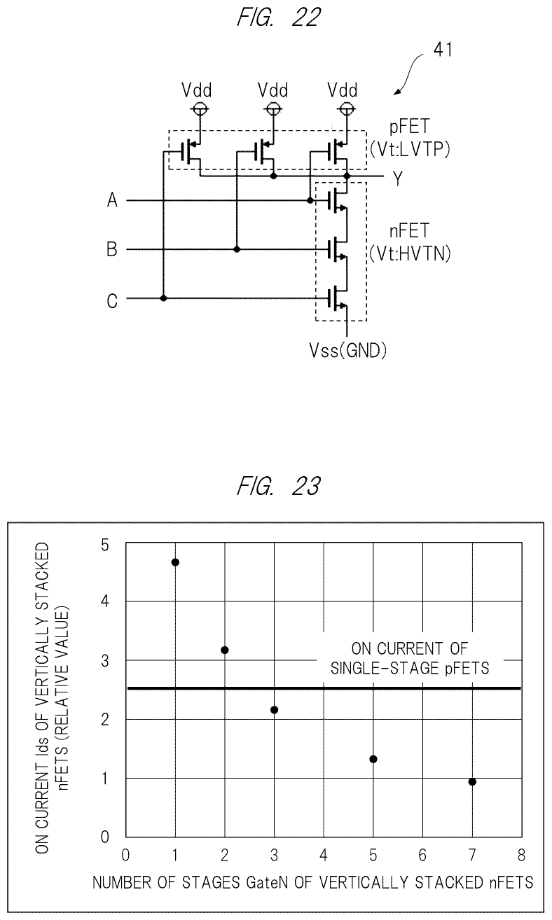

As illustrated in FIG. 22, a NAND circuit type cell 41 according to the fourth embodiment includes a plurality of p-type MOSFETs and a plurality of n-type MOSFETs. The plurality of p-type MOSFETs are connected to the line Vdd on the high potential side of the power supply, which is at the first potential, and are connected in parallel. The plurality of n-type MOSFETs are connected to the line Vss (GND) on the low potential side of the power supply, which is at the second potential, and are connected in series. In the example of FIG. 22, the NAND circuit type cell 41 has a configuration in which three p-type MOSFETs connected in parallel and three n-type MOSFETs connected in series are connected. That is, the NAND circuit type cell 41 has three input terminals A, B, and C and one output terminal Y.

The p-type MOSFETs constituting the NAND circuit type cell 41 has the threshold voltage LVTP. The n-type MOSFETS constituting the NAND circuit type cell 41 has the threshold voltage HVTN. That is, the NAND circuit type cell 41 is an example of the LVT(p)&HVT(n) cell.

Here, a characteristic relating to the ON current in the NAND circuit type cell 41 will be considered. In the NAND circuit, when the number of input terminals increases, both the number of p-type MOSFETs connected in parallel and the number of n-type MOSFETs connected in series increase. Even when the number of p-type MOSFETs connected in parallel increases, the ON current of the entire p-type MOSFETs connected in parallel does not fall below the ON current of the single-stage p-type MOSFET. On the other hand, when the number of n-type MOSFETs connected in series, that is, the number of stages of the vertically stacked n-type MOSFETs increases, internal resistance of the entire n-type MOSFETs connected in series increases, and the ON current of the entire n-type MOSFETs connected in series, that is, vertically stacked decreases.

Therefore, when the number of input terminals of the NAND circuit type cell, that is, the number of stages of the vertically stacked n-type MOSFETs is less than a certain number, the ON current of the vertically stacked n-type MOSFETs is greater than the ON current of the single-stage p-type MOSFETs. However, when the number of input terminals, that is, the number of stages of vertically stacked n-type MOSFETs becomes a certain number or more, the ON current of the vertically stacked n-type MOSFETS becomes the ON current of the single-stage p-type MOSFETs or less.

FIG. 23 is a graph illustrating an example of a relationship between the number of stages of vertically stacked n-type MOSFETs and the ON current in the NAND circuit type cell. In the example illustrated in FIG. 23, when the number of stages GateN of the vertically stacked n-type MOSFETs becomes three or more, an ON current Ids of the vertically stacked n-type MOSFETS becomes smaller than the ON current of the single-stage p-type MOSFETs. Then, the operation speed of the NAND circuit type cell 41 is limited by the vertically stacked n-type r MOSFETs. Therefore, by applying an HVT(p)&LVT(n) cell instead of the LVT(p)&HVT(n) cell to the NAND circuit type cell 41, there is an advantage in the effect of reducing the leakage current.

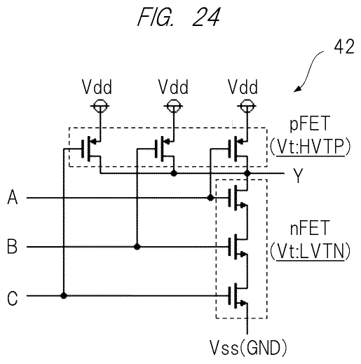

FIG. 24 illustrates an example in which the HVT(p)&LVT(n) cell is applied to the NAND circuit type cell. As illustrated in FIG. 24, the p-type MOSFET constituting a NAND type cell 42 has the threshold voltage HVTP. Further, the n-type MOSFET constituting the NAND type cell 42 has the threshold voltage LVTN. That is, the NAND type cell 42 is an example of the HVT(p)&LVT(n) cell.

As described above, in the NAND circuit type cell, whether to apply the LVT(p)&HVT(n) cell or the HVT(p)&LVT(n) cell may be determined according to the number of stages of the vertical stacked n-type MOSFETs such that there is an advantage in the effect of reducing the leakage current.

In the foregoing, the invention made by the inventors of the present application has been concretely described on the basis of the embodiments. However, it is needless to say that the present invention is not limited to the foregoing embodiments, and various modifications and alterations can be made within the scope of the present invention. Further, the semiconductor device according to each embodiment can be applied to any product as long as the product uses the digital circuit. A part of the contents described in the above-mentioned embodiments will be described below.

### Appendix 1

A semiconductor device including:
a first cell being a logic gate, the first cell including:
   a first p-channel MOSFET; and
   a first n-channel MOSFET;
a second cell being a logic gate, the second cell including:
   a second p-channel MOSFET; and
   a second n-channel MOSFET; and
a third cell being a logic gate, the third cell including:
   a third p-channel MOSFET; and
   a third n-channel MOSFET,
in which the p-channel MOSFET of the first cell has a first threshold voltage,
the n-channel MOSFET of the first cell has a second threshold voltage,
the p-channel MOSFET of the second cell has a third threshold voltage,
the n-channel MOSFET of the second cell has a fourth threshold voltage,
the p-channel MOSFET of the third cell has the first threshold voltage,
the n-channel MOSFET of the third cell has a sixth threshold voltage,
an absolute value of the first threshold voltage is higher than an absolute value of the third threshold voltage,
an absolute value of the second threshold voltage is higher than an absolute value of the fourth threshold voltage, and
an absolute value of the sixth threshold voltage is higher than the absolute value of the first threshold voltage.

### Appendix 2

A semiconductor device including:
a first cell being a logic gate, the first cell including first p-channel MOSFET and a first n-channel MOSFET;
a second cell being a logic gate, the second cell including a second p-channel MOSFET and a second n-channel MOSFET; and
a third cell being a logic gate, the third cell including a third p-channel MOSFET and a third n-channel MOSFET,
in which the p-channel MOSFET of the first cell has a first threshold voltage,
the n-channel MOSFET of the first cell has a second threshold voltage,
the p-channel MOSFET of the second cell has a third threshold voltage,
the n-channel MOSFET of the t second cell has a fourth threshold voltage,
the p-channel MOSFET of the third cell has the first threshold voltage,
the n-channel MOSFET of the third cell has the fourth threshold voltage,
an absolute value of the first threshold voltage is higher than an absolute value of the third threshold voltage,
an absolute value of the second threshold voltage is higher than an absolute value of the fourth threshold voltage, and
the third cell is a NAND gate having three or more input terminals.

What is claimed is:

1. A semiconductor device comprising:
a first cell being a logic gate, the first cell including:
a first p-channel MOSFET connected to a first potential; and
a first n-channel MOSFET connected to a second potential lower than the first potential;
a second cell being a logic gate, the second cell including:
a second p-channel MOSFET connected to the first potential; and
a second n-channel MOSFET connected to the second potential; and
a third cell being a logic gate, the third cell including:
a third p-channel MOSFET connected to the first potential; and
a third n-channel MOSFET connected to the second potential,
wherein the first p-channel MOSFET has a first threshold voltage,
wherein the first n-channel MOSFET has a second threshold voltage,
wherein the second p-channel MOSFET has a third threshold voltage,
wherein the second n-channel MOSFET has a fourth threshold voltage,
wherein the third p-channel MOSFET has the third threshold voltage,
wherein the third n-channel MOSFET has the second threshold voltage,
wherein an absolute value of the first threshold voltage is higher than an absolute value of the third threshold voltage, and
wherein an absolute value of the second threshold voltage is higher than an absolute value of the fourth threshold voltage.

2. The semiconductor device according to claim 1,
wherein the first p-channel MOSFET and the first n-channel MOSFET each have a first gate insulation film,
wherein the second p-channel MOSFET and the second n-channel MOSFET each have a second gate insulation film,
wherein the third p-channel MOSFET and the third n-channel MOSFET each have a third gate insulation film, and
wherein a thickness of the first gate insulation film, a thickness of the second gate insulation film, and a thickness of the third gate insulation film are equal to each other.

3. The semiconductor device according to claim 2,
wherein the first p-channel MOSFET has a channel having a first impurity concentration,
wherein the first n-channel MOSFET has a channel having a second impurity concentration,
wherein the second p-channel MOSFET has a channel having a third impurity concentration,
wherein the second n-channel MOSFET has a channel having a fourth impurity concentration,
wherein the third p-channel MOSFET has a channel having the third impurity concentration, and
wherein the third n-channel MOSFET has a channel having the second impurity concentration.

4. The semiconductor device according to claim 2,
wherein the first p-channel MOSFET has a well having a first impurity concentration,
wherein the first n-channel MOSFET has a well having a second impurity concentration,
wherein the second p-channel MOSFET has a well having a third impurity concentration,
wherein the second n-channel MOSFET has a well having a fourth impurity concentration,
wherein the third p-channel MOSFET has a well having the third impurity concentration, and
wherein the third n-channel MOSFET has a well having the second impurity concentration.

5. The semiconductor device according to claim 1, further comprising:
a first flip-flop circuit and a second flip-flop circuit operating in synchronization with a same clock signal; and
a combination circuit connected between the first flip-flop circuit and the second flip-flop circuit,
wherein the third cell is included in the combination circuit.

6. A semiconductor device comprising:
a first cell being a logic gate, the first cell including a first p-channel MOSFET and a first n-channel MOSFET;
a second cell being a logic gate, the second cell including a second p-channel MOSFET and a second n-channel MOSFET; and
a third cell being a logic gate, the third cell including a third p-channel MOSFET and a third n-channel MOSFET,
wherein the p-channel MOSFET of the first cell has a first threshold voltage,
wherein the n-channel MOSFET of the first cell has a second threshold voltage,
wherein the p-channel MOSFET of the second cell has a third threshold voltage,
wherein the n-channel MOSFET of the second cell has a fourth threshold voltage,
wherein the p-channel MOSFET of the third cell has a fifth threshold voltage,
wherein the n-channel MOSFET of the third cell has the fourth threshold voltage,
wherein an absolute value of the first threshold voltage is higher than an absolute value of the third threshold voltage,
wherein an absolute value of the second threshold voltage is higher than an absolute value of the fourth threshold voltage, and
wherein an absolute value of the fifth threshold voltage is lower than the absolute value of the third threshold voltage.

7. The semiconductor device according to claim 1, further comprising:
a digital circuit portion and a non-digital circuit portion,
wherein the digital circuit portion includes the first cell, the second cell, and the third cell.

8. A method of manufacturing a semiconductor device, the method comprising:
(a) preparing a semiconductor substrate; and
(b) forming a first p-channel MOSFET, a first n-channel MOSFET, a second p-channel MOSFET, a second n-channel MOSFET, a third p-channel MOSFET, and a third n-channel MOSFET on the semiconductor substrate,
wherein the first p-channel MOSFET and the first n-channel MOSFET configure a first cell,
wherein the second p-channel MOSFET and the second n-channel MOSFET configure a second cell,
wherein the third p-channel MOSFET and the third n-channel MOSFET configure a third cell,
wherein the first p-channel MOSFET has a first threshold voltage and is connected to a first potential,
wherein the first n-channel MOSFET has a second threshold voltage and is connected to a second potential lower than the first potential,
wherein the second p-channel MOSFET has a third threshold voltage and is connected to the first potential,
wherein the second n-channel MOSFET has a fourth threshold voltage and is connected to the second potential,
wherein the third p-channel MOSFET has the third threshold voltage and is connected to the first potential,
wherein the third n-channel MOSFET has the second threshold voltage and is connected to the second potential,
wherein an absolute value of the first threshold voltage is higher than an absolute value of the third threshold voltage, and
wherein an absolute value of the second threshold voltage is higher than an absolute value of the fourth threshold voltage.

9. The method according to claim 8,
wherein the first p-channel MOSFET and the first n-channel MOSFET each have a first gate insulation film,
wherein the second p-channel MOSFET and the second n-channel MOSFET each have a second gate insulation film,
wherein the third p-channel MOSFET and the third n-channel MOSFET each have a third gate insulation film, and
wherein the method further comprises:
(c) after the (a), forming an insulation film on the semiconductor substrate; and
(d) processing the insulation film to form the first gate insulation film, the second gate insulation film, and the third gate insulation film.

10. The method according to claim 9, further comprising:
(e) after the (a), forming a first p-type well, a second p-type well, and a third p-type well by implanting p-type impurities into the semiconductor substrate;
(f) forming a first n-type well, a second n-type well, and a third n-type well by implanting n-type impurities into the semiconductor substrate;
(g) forming a first mask film on the semiconductor substrate, the first mask film covering the second n-type well, the third n-type well, the first p-type well, the second p-type well, and the third p-type well and exposing a channel of the first n-type well;
(h) after the (g), implanting n-type impurities into the channel of the first n-type well by using the first mask film;
(i) forming a second mask film on the semiconductor substrate, the second mask film covering the first n-type well, the second n-type well, the third n-type well, and the second p-type well and exposing a channel of the first p-type well and a channel of the third p-type well;
(j) after the (i), implanting p-type impurities into the channel of the first p-type well and the channel of the third p-type well by using the second mask film;
(k) forming a third mask film on the semiconductor substrate, the third mask film covering the first n-type well, the first p-type well, the second p-type well, and the third p-type well and exposing a channel of the second n-type well and a channel of the third n-type well;
(l) after the (k), implanting n-type impurities into the channel of the second n-type well and the channel of the third n-type well by using the third mask film;
(m) forming a fourth mask film on the semiconductor substrate, the fourth mask film covering the first n-type well, the second n-type well, the third n-type well, the first p-type well, and the third p-type well and exposing a channel of the second p-type well; and
(n) after the (m), implanting p-type impurities into the channel of the second p-type well using the fourth mask film,
wherein the first p-channel MOSFET has the first n-type well,
wherein the first n-channel MOSFET has the first p-type well,
wherein the second p-channel MOSFET has the second n-type well,
wherein the second n-channel MOSFET has the second p-type well,
wherein the third p-channel MOSFET has the third n-type well, and
wherein the third n-channel MOSFET has the third p-type well.

11. The method according to claim 10,
wherein an impurity concentration in the channel of the first n-type well is higher than an impurity concentration in the channel of the second n-type well and an impurity concentration in the channel of the third n-type well, and
wherein an impurity concentration in the channel of the first p-type well and an impurity concentration in the channel of the third p-type well are higher than an impurity concentration in the channel of the second p-type well.
